(19) United States
(12) Patent Application Publication
(10) Pub. No.: US 2026/0231735 A1
(43) Pub. Date: Aug. 6, 2026

(54) IN-SITU HYBRID BONDING TEST MEASUREMENTS

(71) Applicant: Tokyo Electron Limited, Tokyo (JP)

(72) Inventors: Partha MUKHOPADHYAY, Oviedo, FL (US); H. Jim FULFORD, Marianna, FL (US)

(73) Assignee: Tokyo Electron Limited, Tokyo (JP)

(21) Appl. No.: 19/045,438

(22) Filed: Feb. 4, 2025

(51) Int. Cl. H01L 21/66; H01L 21/67; H01L 21/768

(52) U.S. Cl. CPC H10P 74/238; H10P 72/0604; H10P 74/203; H10W 20/081

(57) ABSTRACT

In-situ hybrid bonding test measurements are provided. A method includes providing a plurality of first contacts of a daisy chain structure on a first substrate and a plurality of second contacts of the daisy chain structure on a second substrate, the plurality of second contacts configured to align with the plurality of first contacts, respectively. The method includes annealing the first substrate and the second substrate to electrically couple the plurality of first contacts to the plurality of second contacts, respectively. The method includes detecting, while annealing the first substrate and the second substrate, a resistance between a first terminal contact of the daisy chain structure and a second terminal contact of the daisy chain structure. The method includes adjusting at least one of an annealing time or an annealing temperature based on the resistance.

### TECHNICAL FIELD

This disclosure relates to microelectronic devices including semiconductor devices, transistors, and integrated circuits, including methods of microfabrication and test.

### BACKGROUND

The bonding of layers to form 3D structures is of growing importance in the semiconductor manufacturing industry. For example, semiconductor wafers or reconstituted wafers may be generated with circuit components such as logic, memory and/or passive devices. In order to combine devices in the z-plane, multiple wafers or other substrates may be bonded together by a bonding process. In some instances, electrical connections are provided on each substrate and connected as part of the bonding process in what is generally termed hybrid bonding. The connections may be provided as copper (Cu) pads and may have a small size and/or pitch (e.g., 5-micron pitch and/or feature size and below). Due to material characteristics and manufacturing challenges, lateral alignment and connection of these fine features can be difficult. Vertical alignment, referring to a recess of contacts (e.g., Cu pillars for the Cu pads) from a substrate surface, may also prove challenging. Recesses may form according to a differing coefficient of expansion relate to the substrate. However, the depth of the recess may further vary over a surface of the substrate due to temperature asymmetries, dishing effects, wafer warpage, and so forth.

### SUMMARY

Described herein are structures and techniques that provide or improve 3D structures and circuits created using hybrid bonding. Abbreviated yield times may avoid certain defects such as excessive dopant or interlayer diffusion, oxide growth, film stress, silicide degradation, or crystallographic defects such as dislocations. However, these annealing times may be insufficient to electrically and mechanically couple at least some corresponding contacts, (e.g., copper contacts, such as copper pillar contacts), as may lead to manufacturing defects, in-service failures, or reduced performance. An in-situ hybrid bonding test measurement structure can be achieved using contacts of a daisy chain of contact connected between the substrates. For example, electrical properties (e.g., impedance or continuity) of the test structure can be measured at terminal contacts of the daisy chain during an annealing process. By adjusting process parameters of the in-situ measurements, during an annealing process, yields of bonded technology devices can be improved, to reduce anneal times while preserving the connections between the conductive elements.

In one embodiment, a method may include bonding a first substrate with a second substrate. The method may include monitoring a characteristic of the bonded first and second substrate. The method may include while monitoring, annealing the first substrate and the second substrate under a set of conditions. The method may include adjusting the set of conditions when the characteristic reaches a desired state.

The first substrate can be or include a wafer; the second substrate can be or include a die. The first substrate includes, disposed along a same surface coupled with the die: a first terminal contact for a plurality of first contacts of a daisy chain structure and a second terminal contact for a plurality of second contacts of the daisy chain structure.

The first terminal contact can include a through-substrate via structure, wherein the through-substrate via structure is exposed on a rear surface of the second substrate by removing a portion of the second substrate.

The first substrate and the second substrate can be coupled in a front-to-front configuration. The first terminal contact and the second terminal contact can be disposed on a backside of the second substrate.

The set of conditions can include at least one of an annealing time or an annealing temperature. The desired state can be determined using a resistance of an electrical connection between the first substrate and the second substrate.

The method can include mapping a plurality of annealing temperature resistance values of a daisy chain structure including a plurality of first contacts of the first substrate coupled with a plurality of second contacts of the second substrate to a corresponding plurality of ambient resistance values. The method can include mapping the plurality of ambient resistance values to a plurality of device yields. The method can include halting the anneal responsive to detecting the resistance, wherein the desired state includes a value of an annealing temperature resistance corresponding to an ambient resistance value correlating to a highest device yield.

The first contacts and the second contacts can include contacts of the daisy chain structure including contacts disposed over a scribe line of at least one of the first substrate or the second substrate.

The daisy chain structure can consist essentially of the first contacts and first lines coupling the first contacts to one-another; the second contacts and second lines coupling the second contacts to one-another and first and second terminal contacts and any lines coupling the first and second terminal contacts with the first contacts.

The second substrate can laterally overlap with a scribe line and include at least a portion of the plurality of second contacts within an active die area.

The method can include annealing the first substrate with the second substrate using a heated chuck having a plurality of separately engageable heating zones, wherein further terminal contacts are coupled with further daisy chain structures. The method can include adjusting the set of conditions includes adjusting a first temperature of a first of the plurality of separately engageable heating zones based on a detected resistance. The method can include adjusting the set of conditions includes adjusting a second temperature of a second of the plurality of separately engageable heating zones based on a second detected resistance, the second detected resistance detected via one of the further terminal contacts.

The method can include separately engaging the separately engageable heating zones to individually control bonding of the first substrate with the second substrate and a plurality of further substrates, based on a plurality of other detected resistances corresponding to annealing with each of the further substrates. The first substrate can include a wafer and the second substrate and the further substrates can include cut dies.

In another embodiment, a method may include providing a plurality of first contacts of a daisy chain structure on a first substrate and a plurality of second contacts of the daisy chain structure on a second substrate, the plurality of second contacts configured to align with the plurality of first contacts; annealing the first substrate and the second substrate to electrically couple the plurality of first contacts to the plurality of second contacts; detecting, while annealing the first substrate and the second substrate, a resistance between a first terminal contact of the daisy chain structure and a second terminal contact of the daisy chain structure; and adjusting at least one of an annealing time or an annealing temperature based on the resistance.

The first substrate may be a wafer, and the second substrate may be a die; and the first substrate may include the first terminal contact and the second terminal contact disposed along a same surface coupled with the die.

The first substrate and the second substrate may be coupled in a front-to-front configuration; and the first terminal contact and the second terminal contact may be disposed on a backside of the second substrate.

The first substrate is a wafer may include a plurality of circuits, wherein the first terminal contact and the second terminal contact are provided for only one of the circuits.

The method may further comprise mapping a plurality of annealing temperature resistance values to a corresponding plurality of ambient resistance values; mapping the plurality of ambient resistance values to a plurality of device yields; and halting the anneal responsive to detecting the resistance, wherein a value of the resistance is an annealing temperature resistance corresponding to an ambient resistance value correlating to a highest device yield.

The first contacts and the second contacts of the daisy chain structure may include contacts disposed over a scribe line of at least one of the first substrate or the second substrate.

The daisy chain structure may consist essentially of the first contacts and first lines coupling the first contacts to one-another; the second contacts and second lines coupling the second contacts to one-another; and the first and second terminal contacts and any lines coupling the first and second terminal contacts with the first contacts.

The first terminal contact may include a through-substrate via structure, wherein the through-substrate via structure is exposed on a rear surface of the second substrate (e.g., a top die) by removing a portion of the second substrate (e.g., a die or full wafer).

The second substrate may laterally overlap with a scribe line and includes at least a portion of the plurality of the second contacts within an active die area.

The method may further include bonding the first substrate with the second substrate using a heated chuck having a plurality of separately engageable heating zones, wherein further terminal contacts are coupled with further daisy chain structures; adjusting a first temperature of a first of the plurality of separately engageable heating zones based on the detected resistance; and adjusting a second temperature of a second of the plurality of separately engageable heating zones based on a second detected resistance, the second detected resistance detected via one of the further terminal contacts.

The method may further include: separately engaging the separately engageable heating zones to individually control bonding of the first substrate with the second substrate and a plurality of further substrates, based on: the detected resistance; and a plurality of other detected resistances corresponding to a bonding with each of the further substrates, wherein: the first substrate is a wafer; and the second substrate and the further substrates are cut dies.

In another embodiment, a method may include: bonding a first substrate including a plurality of first contacts to a second substrate including a plurality of second contacts; heating the first and second substrates to a first temperature configured to electrically couple the plurality of first contacts with corresponding ones of the plurality of second contacts; detecting, at the first temperature, continuity between a first terminal contact and a second terminal contact coupled with the plurality of first and second contacts; adjusting, based on the detection of continuity, a first process parameter of an anneal process to couple the first substrate with the second substrate; detecting, subsequent to adjusting the first process parameter, an impedance between the first terminal contact and the second terminal contact; and adjusting, based on the detection of continuity, a second process parameter of the anneal process based on a comparison of the impedance to an impedance threshold.

The adjustment to the second process parameter may include a termination of the anneal process.

The impedance may be a resistance.

The adjustment to the first process parameter may include an adjustment to an annealing time; or an adjustment to an annealing temperature (e.g., a combination of both of the anneal temperature and the anneal time).

The method may further include comparing the impedance to a mapping between the first temperature and another impedance at a second temperature; and terminating the annealing process based on the mapping.

The method may further include regularly detecting the impedance; and iteratively adjusting the second process parameter.

In another embodiment, a system may include: a heated chuck including: a plurality of separately engageable heating zones; and a plurality of terminal pairs configured to couple with corresponding terminals of a semiconductor device including a first substrate and at least one second substrate; and a controller configured to: receive, from the plurality of terminal pairs, a corresponding plurality of measurements at the plurality of terminal pairs; and adjust, based on the plurality of measurements, a temperature of the separately engageable heating zones.

The plurality of measurements may include a plurality of resistance measurements; and the controller may be further configured to: compare the plurality of resistance measurements to a threshold resistance value; and adjust the temperature of the separately engageable heating zones to converge the plurality of resistance measurements to a same value.

The same value may be an ambient temperature resistance value.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a pair of substrates to be bonded and electrically connected, in accordance with some embodiments.

FIG. 2 illustrates a cross sectional view of a bonded substrate pair including paired contact structures, in accordance with some embodiments.

FIG. 3 illustrates a cut view of a first metallization layer of an in-situ test structure, in accordance with some embodiments.

FIG. 4 illustrates a cut view of various first contacts coupled with the first metallization layer of the in-situ test structure of FIG. 3, in accordance with some embodiments.

FIG. 5 illustrates a cut view of a second metallization layer of the in-situ test structure of FIGS. 3-4, in accordance with some embodiments.

FIG. 6 illustrates a cut view side view of the in-situ test structure of FIGS. 3-5, in accordance with some embodiments.

FIG. 7 illustrates a wafer coupled with various dies and a multi-zone chuck, in accordance with some embodiments.

FIG. 8 is a flow chart of a method for making a semiconductor device, in accordance with some embodiments.

FIG. 9 depicts an example block diagram of an example computer system, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more semiconductor devices including bonded substrates. The bonds between the substrates can include dielectric bonds relying on Van Der Waals forces and metal-to-metal bonds relying on a coupling of conductive contacts. Generally, the metal-to-metal bonds are emplaced subsequent to the dielectric bonds. For example, the dielectric bonds can be realized according to an interface between planarized surfaces of two substrates, which already include corresponding metal contacts of a metal contact pair. The metal contacts may be somewhat recessed from the planarized surfaces (e.g., a few or several nanometers) and thus may not interfere with the formation of the dielectric bonds. Subsequent to the formation of the hybrid bonds, an anneal operation heats the bonded substrates to expand the volume of the recessed metal contacts, causing the paired metal contacts to expand end eventually meet.

Once the paired metal contacts reach one-another, the respective materials will diffuse across an interface therebetween, and may ultimately recrystallize into grains which eliminate the original interface. The paired metal contacts reaching one-another may be detected according using test instrumentation during the annealing process. For example, a continuity (opens/shorts) test can detect conduction across the respective contacts. Similarly, grain growth and diffusion can correlate to a measurable property of the coupled contact (e.g., impedance). Measuring these values subsequent to completion of an annealing process can provide useful estimates as to the performance of a bonded substrate pair. Moreover, where such values are detected in-situ, during an annealing process, process parameters of the annealing can be adjusted based on the detected properties of the bonds.

It may be challenging to detect a property of a single bond, particularly so at elevated and varying temperature. However, by arraying multiple contacts into a daisy chain test structure including hundreds or thousands of interfaces, a gross property of the test structure can vary substantially based on a small change to a property at each of the interface instances (e.g., resistance across the interfaces). Moreover, the presence of multiple interfaces in a test structure can reduce the impact of outlier values (e.g., a contact having a void). The test structure can include terminal contacts configured to couple with a test device. The terminal contacts can include, for example, landing pads, as may be configured to couple with soldered probes, pogo pins, or other instrumentation. In some embodiments, the terminal contacts are disposed along the bonding surface. For example, where substrates having different lateral dimensions are bonded to one-another, terminal contacts may be disposed along the bonding surface on the larger of the substrate on a portion which does not overlap with the smaller of the substrate (sometimes referred to as an overhang portion). Where substrates of a same or similar size are bonded (e.g., in the case of wafer-to-wafer bonding), the bonding surface may be inaccessible to couple test probes with. However, a through-substrate via structure can be provided to expose the terminal contact on a backside of at least one of the bonded pair of substrates.

In cases where a substrate otherwise lacks backside contacts, the through-substrate via structure can be provided according to techniques departing from other components of the substrate pair. Such a backside substrate may not confirm to design rule checks, and may be formed according to differing materials or processes as the other connections of the coupled substrate pair. For example, a vis structure may be manually drilled and solder-filled, as opposed to lithographically formed, in some embodiments. Although such techniques can contribute variance to a measurable property of the test structure, the gross measurement of the various contacts (e.g., hundreds or thousands) can exceed such variance, so as to provide actionable insights into the state of the bond between the substrates.

Process parameters can be adjusted during the annealing process based on the measured values. Process parameters include, for example, an annealing temperature, annealing time, annealing ramp rate, or so forth. Process parameters can be varied on a per-die, per-wafer, per-pod, per-oven, or other basis. For example, a multi-zonal heated chuck can be configured to separately heat various zones, based on multiple test structures across the zones. An annealing oven can be configured to adjust a temperature based on one or more test structures in the oven. Modulating various process parameters can improve yields of semiconductor devices. Moreover, modulating a total annealing time downwards can reduce energy use, carbon emissions, or machine time. Further, the decreased machine time can, in turn, increase total throughout, or decrease a number or size of annealing chambers (sometimes referred to as ovens or heated chucks) for a given thruput.

In some cases, in-situ measured values will depart from a similar value as measured subsequent to completion of the annealing process. For example, copper pillars used for hybrid bonding can exhibit higher resistance at annealing temperature than ambient temperatures. However, an in-situ measured value can be correlated with an ambient value. Such correlation can normalize in-situ measured values taken at different temperatures, or be used to include further ambient temperature data, as may be measured according destructive or non-destructive techniques. Accordingly, to adjust the process parameter, an in-situ measured value can be mapped to an ambient value, and an adjustment can be based on the mapped value.

Sets of terminal contacts can provide on a per-circuit (e.g., per-die) basis, per-wafer-basis, or so forth. For example, a heated chuck can include connectors configured to electrically couple with various terminal contact pairs to detect an impedance of various circuits. Sets of terminal contacts can include a pair (2T) of terminal contacts to detect resistance or other aspects of independence, three terminal (3T) or four terminal (4T) sensing to detect impedance or other aspects, or so forth. Various examples provided herein sometimes refer to pairs of contacts. However, these contact pairs can be substituted for other configurations (e.g., 3T or 4T configurations).

Although the figures and aspects of the disclosure may show or describe devices herein as having a particular shape, it should be understood that such shapes are merely illustrative and should not be considered limiting to the scope of the techniques described herein. For example, although certain figures show various contacts in a rectangular or cylindrical configuration, other shapes are also contemplated, and indeed the techniques described herein may be implemented in any shape or geometry.

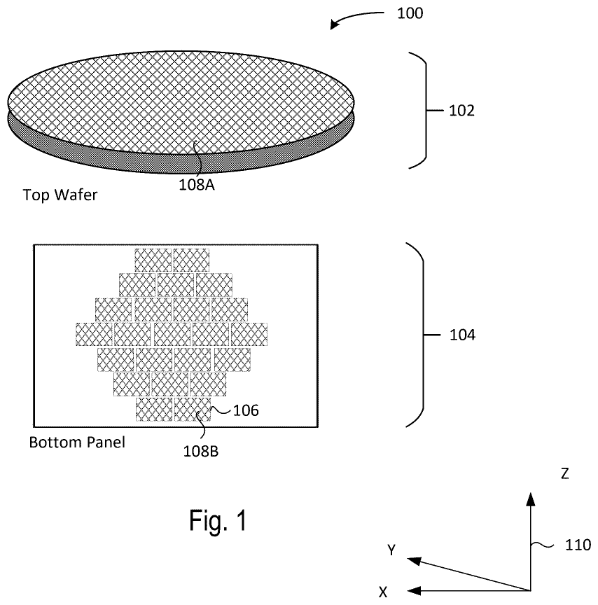

FIG. 1 illustrates a system 100 including a paired set of substrates configured for bonding, such as hybrid bonding. Particularly, the substrates include a top substrate, depicted as a semiconductor wafer 102, and a bottom substrate, depicted as a semiconductor panel 104 including various semiconductor dies 106 configured to interface with the wafer 102. For example, the various semiconductor dies 106 may be diced from one or more further wafers 102. As is depicted, the dies of the panel are spaced from one-another. Terminal contacts may be diposed in such spacings, or be provided on a backside of the wafer 102 or at least one die 106 of the panel 104.

The depicted substrates are merely an illustrative example and should not be construed as limiting. In some embodiments, the upper and lower substrates are both a semiconductor wafer 102 or both a panel 104 and/or other assemblages of one or more semiconductor dies 106. For example, a bonded substrate pair can already be bonded according to a dielectric bond, but not yet be electrically connected. Moreover, a relative position of one or more substrates may be modified or substituted. Indeed, phrases such as “upper,” “lower,” “right,” or “left” should be construed as describing the provided figures and are not intended to limit the scope of the present disclosure. Various embodiments can orient the various elements described here according to various reference directions.

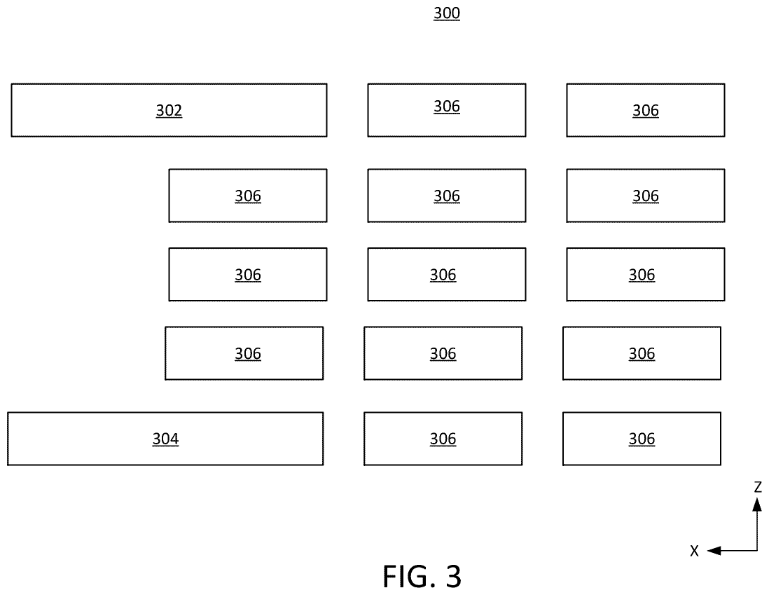

The top substrate includes first contacts 108A and the bottom substrate includes second contacts 108B. Various instances of the first contacts 108A or second contacts 108B may be referred to, generally or collectively, as contacts 108. Each substrate includes various contacts 108 of a paired set of contacts 108. The respective contacts 108A, 108B of the respective substrates are configured to interface with each other, such as to stack a memory die over a logic die to form a three-dimensional integrated circuit (3DIC). A portion of the contacts 108 can include contacts of a test structure formed between substrates (e.g., the in-situ test structure of FIGS. 3-6); another portion of the contacts 108 can convey clocks, memory or data busses, or other components of computational functionality between the substrates.

A provided axis 110 indicates an x-y plane, which may be referred to as a bonding plane, indicative of an interface between the respective substrates. Movement, distances, etc. which extend along the bonding plane are referred to, herein, as lateral movements, lateral distances, lateral dimensions, etc. A z-direction refers to a direction perpendicular to the bonding plane. Similar language, such as a z-height may also be referred to a device height according to a mounting surface or other substrate (e.g., a printed circuit board). Although such a z-height may generally correspond with the z-direction of the axis 110, such correspondence is not limiting and may, in some embodiments, differ therefrom.

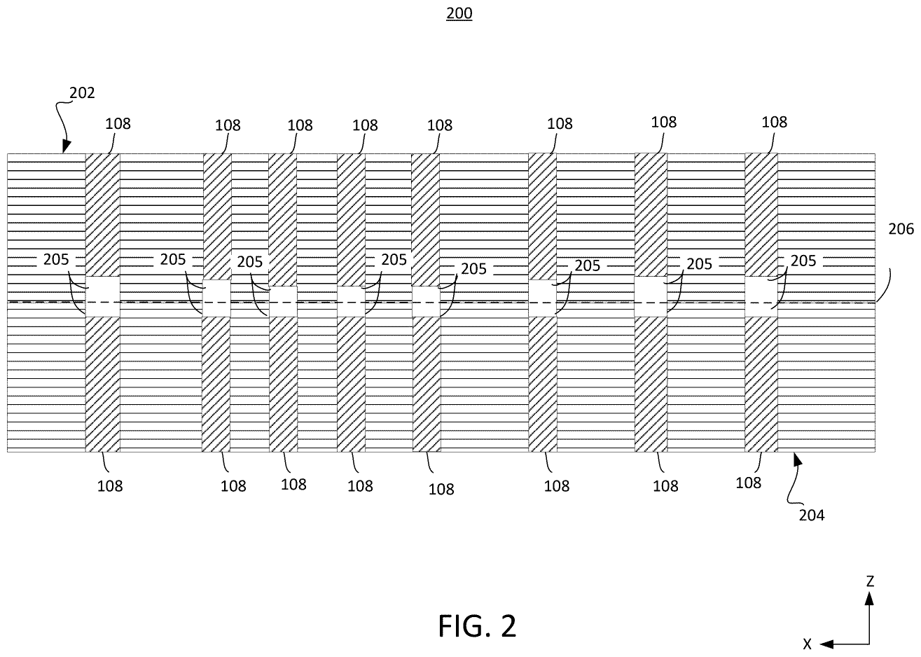

FIG. 2 illustrates a cross sectional view of a semiconductor device 200 including a bonded substrate pair, in accordance with some embodiments. The substate pair includes a top substrate 202 (e.g., a panel 104 or wafer 102, such as the depicted wafer 102 of FIG. 1) and a bottom substrate 204 (e.g., a wafer 102 or panel 104, such as the depicted panel 104 of FIG. 1). A junction of the top substrate 202 and bottom substrate 204 defines a bonding plane 206 which extends laterally upon a generally flat surface of the respective substrates, but which can include vertical variation according to warpage, deviations in thickness, or other attributes of the respective substrates 202, 204.

The depicted condition of the semiconductor device 200 corresponds to a condition of a bonded substrate pair prior to annealing. During an annealing operation, the paired contacts 108 can couple with one-another and occupy the depicted recesses 205. For example, an annealing operation of a bonding process to couple the top substrate 202 with the bottom substrate 204, can apply heat to expand a conductive contact material (e.g., copper) relative to the substrate material (e.g., silicon), and maintain the elevated temperature long enough to bring the upper contacts 108 into contact with the lower contacts 108. Once in contact, electrical continuity can be detected across various contacts (e.g., wherein the various contacts 108 are contacts of a daisy chain test structure). Moreover, electrical properties (e.g., impedance) of the electrical connections between the various contacts can be measured, in aggregate, based on measurement at terminal contacts of the test structure. The elevated temperature can cause diffusion between the contacts (e.g., across the bonding plane 206). The diffusion may correspond to changed electrical properties (e.g., increased resistance). The diffusion may also correspond to increased mechanical strength in tension upon cooling, such that resistance or other electrical properties of the connection during the annealing process can be predictive of mechanical (and electrical) properties upon cooling. Thus, an annealing time (or temperature) can be determined and adjusted based on in-situ measurements as to conductivity, resistance, or other measurements of electrical properties of a test structure.

In some embodiments, instead of or in addition to an oven-type annealing chamber, a wafer handler including at least one heated chuck may be used to electrically connect the substrate pair. For example, at least one of a top chuck configured to mechanically interface with a first wafer of the wafer pair or a bottom chuck configured to mechanically interface with a second wafer of the wafer pair may be a heated chuck. According to such an approach, a temperature profile can be modulated on a per-substrate basis or a per-substrate pair basis. For example, higher heat or longer annealing times may be applied to one wafer relative to other substrates.

In some instances, a zonal heating chuck is configured to heat more than one zone of a substrate or substrate pair differently than other zones of the substrate or substrate pair. For example, a zonal heating chuck can include zones defining according to radial portions of a substrate, concentric portions of a substrate, combinations thereof (e.g., a central zone and two or more radial peripheral zones), or according to further geometries. For example, a zonal heated chuck for a generally rectangular panel can include a rectangular grid of heating zones.

Where a recess 205 depth varies along a surface of a substrate (an example of which is depicted hereinafter at FIG. 3), the various zones of the substrate can be provided with varying temperature profiles. For example, a ramp rate, dwell temperature, or dwell time may be varied over a surface of a substrate pair so as to provide greater expansion and diffusion time for relatively large recesses 205 and lesser expansion and diffusion time for relatively small recesses 205 (as may correlate positively with other aspects of yields, such as by reducing interlayer diffusion, oxide growth, or film stress). The various zones can be based on in-situ measurements corresponding to the zones, or based on predefined offsets (e.g., based on dishing effects from wafer polishing).

In some instances, the contacts 108 of the top substrate 202 may be laterally offset from corresponding contacts 108 of the bottom substrate 204. A resultant misalignment between the contacts 108 can increase a resistance of a connection formed between the corresponding contacts, and may also decrease a mechanical strength of the connection. Misalignment between contacts 108 occurs for a variety of reasons such as material expansion caused by temperature or CTE (coefficient of thermal expansion) mismatch, stretch or shift along a bond interface that may occur as the bonding interface is created and propagates across the substrate, warpage of either substrate, particle interference at the bond interface, or other sources of misalignment. Moreover, the alignment may vary across various portions of the respective substrates. In some instances, processes to correct or mitigate misalignment may be performed such as thermal reflow or alignment re-work. However, such techniques may not always be practical, or may not fully resolve alignment issues. Increased anneal times or temperatures can mitigate the impact of these misalignments by forming robust electrical and mechanical connections across the bonding plane 206 according to the systems and methods of the present disclosure. Moreover, measurements indicative of misalignment can be used to adjust process parameters for future wafers (e.g., to adjust for process-drift over time).

Increasing dwell times of an annealing temperature profile may aid in forming electrical and mechanical connections between contacts 108 of corresponding substrates. For example, extending a highest temperature may be particularly useful for expanding contacts of deep recesses or forming robust mechanical connections for misaligned contacts, either of which can correlate to increased resistance of a test structure and increased time before detection of continuity. Accordingly, even where a basis for an in-situ measurement is not immediately explainable, the present techniques can be used to adjust a fabrication process to improve yields. Moreover, the in-situ can prompt an earlier investigation than may otherwise be undertaken as may further improve yields (e.g., using destructive techniques).

FIG. 3 illustrates a cut view of a first metallization layer of an in-situ test structure 300, in accordance with some embodiments. The first metallization layer can be an uppermost (for a front-to-front bonding configuration) metallization layer of one substrate of a substrate pair bonded or configured for bonding. A first conductive line 302 and second conductive line 304 of the test structure 300 are provided as or to couple with terminal contacts. Various further conductive lines 306 are provided as impregnated into the device (e.g., into a substrate or an inter-layer dielectric (ILD)). The substrate, ILD, and so forth are omitted from the present depiction to more clearly illustrate the conductive lines 302, 304, 306 of the test structure 300.

The terminal contacts are configured to couple with a test device. For example, the test device can include an LCR meter to measure a complex impedance, an ohmmeter to measure a resistive impedance (resistance), or a time-domain reflectometer (TDR) to measure impedance discontinuities. The terminal contacts include a contact pad configured to couple with the test device. The contact pad (not depicted) can be provided with substantially larger dimensions than depicted portions of the metallization layer. For example, contact pads can extend several multiples of the lateral dimensions of the conductive lines 306, as may ease coupling the contact pad with the test device. The coupling can be achieved via manual attachment of a test probe, pogo pins integrated into a chuck, or so forth.

The conductive lines 306 are provided as one part of a daisy chained test structure 300. As measured by terminal contacts coupled with the first conductive line 302 and second conductive line 304 prior to the annealing process, a test instrument would detect an open circuit, since the conductive lines 306 do not connect to one another. However, when coupled with corresponding conductive element of another substrate, a resistance of the test structure can be measured and mapped to an ambient value. The ambient value can be compared to a threshold, and a process parameter can be adjusted based on the comparison.

The resistance can include a first resistive component of the resistance of the depicted conductive lines 306 and the conductive elements of the other substrate. A second resistive component can represent contacts 108 (e.g., copper pillars) coupling the metallization layers of the substrates to one-another. This can include the contacts 108 themselves, along with any interfaces, such as a first interface between contacts 108 and the depicted conductive lines 306, a second interface between corresponding contacts 108 along the bonding plane 206, and a third interface between the contacts 108 and metallization layer of the other substrate. A third resistive component can relate to the terminal contacts themselves. However, its relative contribution of variance to the total resistance can be reduced by increasing a number of conductive lines 306 included in the test structure. For example, even a variance of several ohms can be dominated by test structure variance of tens, hundreds, or thousands of ohms along a hybrid bond interface.

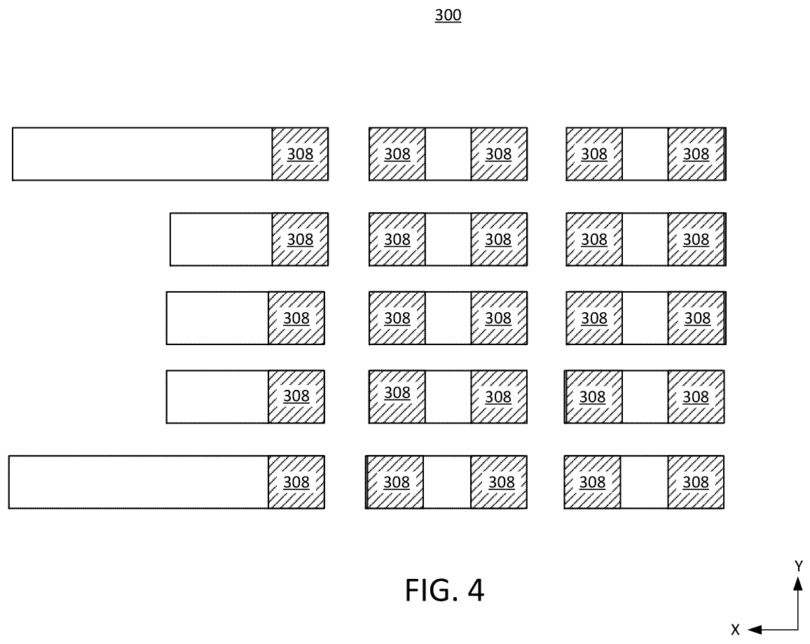

FIG. 4 illustrates a cut view of various first contacts 308 coupled with the first metallization layer of the in-situ test structure, in accordance with some embodiments. The first contacts 308 can be provided in a same substrate (e.g., into a semiconductive substrate or ILD formed over various metallization layers over the semiconductive substrate). The first contacts 308 can include copper pillars terminating at copper pads at an outer surface of the substrate, and be configured to couple with corresponding second contacts 310 of another substrate. For example, the depicted cut view can correspond to a bonding plane 206, such that the corresponding second contacts 310 can be immediately above the depicted first contacts 308 (or slightly offset therefrom, according to any misalignment). Post-annealing, the corresponding second contacts 310 can electrically and mechanically couple with, and diffuse into, the depicted first contacts 308.

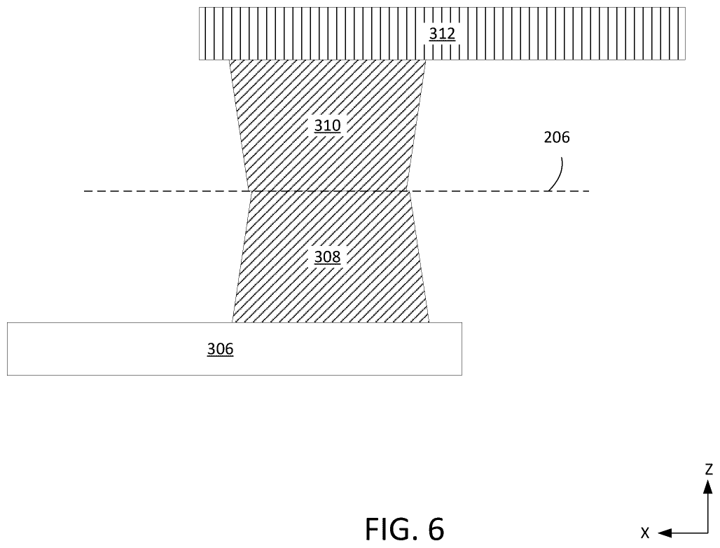

As indicated above, first contacts 308 and corresponding second contacts 310 can exhibit some misalignment. However, first contacts 308 and second contacts can be positioned to nominally overlap with one-another, as is depicted in FIG. 6, henceforth. Accordingly, a further cut view of a bonded substrate pair somewhat vertically over the depicted cut view, would depict corresponding second contacts 310 in substantially similar positions to the first contacts 308 of the present figure, and is omitted to avoid duplicative figures. However, such an illustrative example should not be construed as limiting. For example, in some embodiments, the corresponding second contacts 310 can be provided as somewhat offset from, larger (or smaller) than, or of a different shape than the first contacts. A substrate or ILD is depicted transparently, such that the conductive lines 302, 304, 306 vertically below the depicted cut plane are visible.

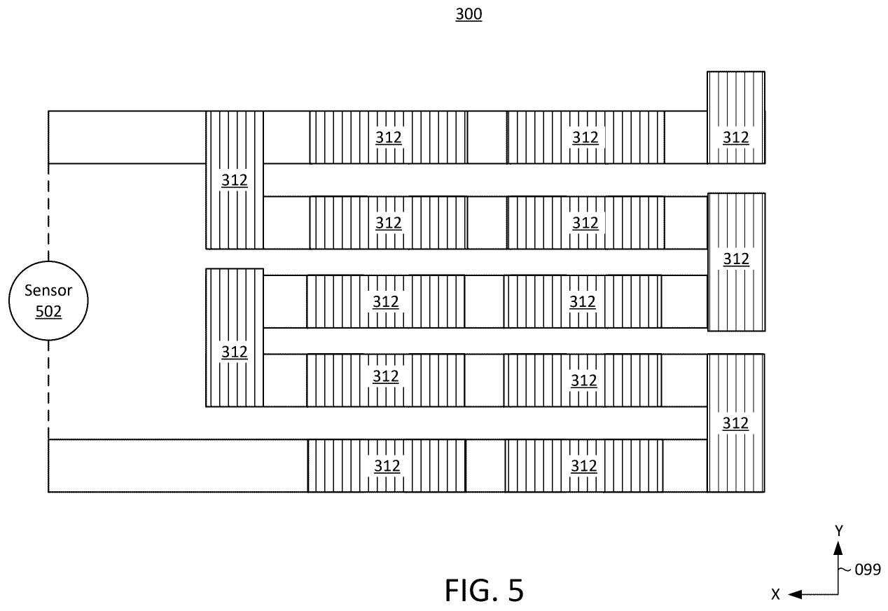

FIG. 5 illustrates a cut view of a second metallization layer of the in-situ test structure 300, in accordance with some embodiments. The depicted cut view is taken along a plane vertically spaced from the cut plane of FIG. 4, and also vertically spaced from the discussed (but not depicted) cut plane including the corresponding second contacts 310. Such a cut plane is disposed within a different substrate of a bonded substrate pair, than the substrate of FIG. 4. That is, a bonding plane 206 is disposed between the present cut plane and the cut plane of FIG. 3. Conductive lines 312 provided within the depicted cut plane are thus vertically offset across the bonding plane 206, from the conductive lines 306 of FIGS. 3-4. When connected by the first contacts 308 and corresponding second contacts 310, the test structure 300 is electrically continuous between the first conductive line 302 and second conductive line 304. Although depicted as tens of connections, various embodiments of the present disclosure can include additional connections (e.g., hundreds of additional connections, thousands of additional connections, tens of thousands of additional connections, or so forth). As for FIG. 4, a substrate or ILD is depicted transparently, such that the conductive lines 302, 304, 306 vertically below the depicted cut plane are visible.

A sensor 502 is depicted as (logically) coupled between the first conductive line 302 and second conductive line 304 of the test structure 300. The sensor 502 can be configured to detect an impedance of the test structure 300. The sensor 502 can be coupled with the depicted test structure 300 via further landing pads, TSV, or other conductive elements. For example, the sensor 502 can be coupled with one test structure 300 during an annealing process, and another test structure 300 of another substrate pair during a subsequent annealing process. In some embodiments, the sensor 502 is coupled with or integral to a chuck or other component, or is provided as a further device external to the top substrate 202 and bottom substrate 204.

FIG. 6 illustrates a cut view side view of a the in-situ test structure of FIGS. 3-5, in accordance with some embodiments. As for FIGS. 4-5, a substrate or ILD is depicted transparently. Coupled components of a conductive line 306 and a first contact 308 of a first substrate are depicted as coupled with a conductive line 312 and a second contact 310 of a second substrate. Such a depiction can correspond to an in-situ measurement during the annealing process.

The conductive line 306, 312 and contacts 308, 310 of each of the respective substrates can be or include a same conductive element (e.g., copper). In some embodiments, the conductive lines 306, 312 and contacts 308, 310 are formed according to a same or related process. For example, the conductive lines 306, 312 can be formed along with via structures to couple with further (lower) conductive lines of further metallization layers using a double damascene process. Thereafter, surfaces of each of the substrates can be patterned over the uppermost metallization layer to form the depicted contacts 308, 310 (e.g., copper pillars).

During an annealing process, the contacts 308, 310 come into contact with one another, along a bonding plane 206. Such contact can correspond to a temperature dependent expansion of the contacts, relative to their depiction in FIG. 2. Upon coming into contact with one-another the contacts 308, 310 can become electrically conductive. Accordingly, a test device electrically coupled with the contacts 308, 310 (via a terminal contact) can detect continuity. Although FIG. 6 depicts a single mated contact pair, test structures can include many (e.g., hundreds, thousands, etc.) of contact pairs coupled in series such that the continuity may be detected upon the mating of all of the contact pairs. Accordingly, upon detection of continuity each of the series contact pairs can be determined to be mated with one another. Continuity may refer to a detected resistance relative to a threshold, such as a threshold configured to exclude leakage current of non-electrically coupled contact pairs. In some embodiments, multiple series portions of a test structure 300 can be coupled between a single contact pair. In some embodiments, contact pairs may be selected from various available positions. For example, a series string of contact pairs can terminate at a terminal contact every n contact pairs, such that for 2n contact pairs, 3 terminal contacts are provided.

Although continuity can evidence electrical connection, such electrical connection does not necessarily indicate a completion of an annealing process. For example, when the depicted contacts 308, 310 first come into contact with one another, some electrical conduction can take place, but may be inhibited by oxides formed over the surface of the contacts 308, 310. Moreover, initial connectivity may not prove robust enough to manage tensile forces between the contacts following the anneal operation. For example, the contacts 308, 310 can form a mechanical joint which may not survive cooling, vibration, or may exhibit higher than expected resistance. Accordingly, upon detection of continuity, a process can be adjusted to promote bonding. For example, for copper interconnects, a temperature, time, ramp rate, or other process condition can be adjusted to promote grain growth of the respective contacts 308, 310 proximal to the bonding plane 206. Such a process adjustment based on the detected continuity can increase control over of the bonding process, relative to a predefined temperature profile.

The annealing process can include a first period of time to bring the contacts 308, 310 into contact with one another and a second period of time for cross-diffusion between the contacts 308, 310, cooling, grain growth, etc. Determination of the establishment of continuity can allow an annealing process to vary between the first period and the second period. For example, the first period can be performed below a recrystallization temperature to expand the contacts, and at least a portion of the second period can be performed above a recrystallization temperature to promote diffusion or grain growth. Similarly, ramp rates, hold times, or other process parameters can be adjusted based on a detected conditions (e.g., continuity, independence, or a passage of a predefined time without detecting continuity or reaching another threshold).

The test device may be configured to measure resistance or another property between the contacts 308, 310 of the depicted contact pair as well as any further contacts pairs of the test structure 300. The in-situ resistance can map to a post-anneal resistance. For example, a resistance of 2 kΩ at an oven temperature can correspond to a temperature of 1 kΩ at an ambient temperature, or 4 kΩ when molten. Accordingly, detecting an impedance or other property during an annealing process and comparing the detected value to a threshold can be used to adjust the process. For example, a comparison to a high resistance threshold can be used to adjust a temperature or time downward to avoid melting contacts (as may lead to void formation, trapped contaminants, or so forth). A comparison to a low resistance threshold can be used to adjust a temperature or time upward to promote diffusion across the bonding plane 206. Similarly, detection of resistance can be used to determine a cooling time or ramp rate, as may correspond to grain growth, and further be used to modify another dwell time, ramp rate, or so on.

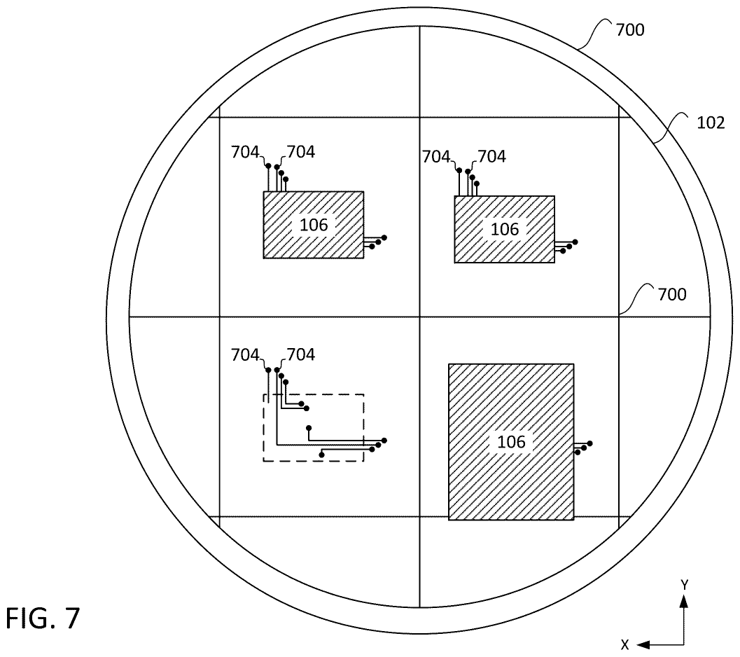

FIG. 7 illustrates a wafer 102 coupled with various dies 106 and a multi-zone chuck 700, in accordance with some embodiments. A peripheral portion of the multi-zone chuck 700 is depicted behind an upper wafer 102. The upper wafer 102 is segmented into constituent circuits, as may be diced into separate dies by cutting along scribe lines 702. For example, the scribe lines 702 may be cut subsequent to bonding. The wafer 102 is depicted as coupled with each of four diced dies 106, to aid with the clarity of the present figures. However, a single wafer 102 can include additional dies (e.g., fifty or one-hundred dies). Scribe lines 702 refer to area prescribed for later cutting, even where fiducial markings, laser-scribing, or other physical features are absent.

According to the depicted illustrative example, the respective substrates (the wafer 102 and each die 106) are coupled in a front-to-front configuration. However, a substrate portion of the wafer 102 is depicted as larger than the dies 106, such that a front surface of at least one substrate (the wafer 102) is exposed. According to such an implementation, terminal contacts 704 may be disposed along the exposed face. Accordingly, a test device can couple with the terminal contacts 704 on the exposed face to monitor the in-situ annealing process according to a detection of impedance, as may include, for example, resistance or continuity measurements. Although depicted as a die/wafer pair, bonded substrates having exposed faces can include other substrate pairs. For example, first and second cut dies of respective panels can be bonded based on in-situ test measurements as received from a test device coupled with terminal contacts along an exposed surface of a larger of the first or second cut dies.

In some embodiments, the test device can be coupled with (e.g., integral to) a chuck. For example, pogo pins of the top or bottom chuck can be configured to electrically couple with terminal contacts 704 disposed on the exposed face. In some cases, further contacts may be disposed on the exposed surface, as may include contacts for open/shorts tests, JTAG connections, or so forth.

In some embodiments, an exposed surface may not be present. For example, two similarly sized wafers 102 or dies 106 may be coupled with one another. However, a through-substrate via structure (TSV, sometimes referred to as a through-silicon-via) can provide terminal contacts 704 on a backside of a pair of substrates. Such a TSV need not conform to various design rules, lithographic dimensions, or other design criteria as may be applied to active portions of a circuit. Accordingly, the TSV can couple with a test structure 300 but need not electrically coupled with other portions of a circuit. Moreover, a small number of TSV may be present on a per-substrate (e.g., per-wafer 102 basis). For example, in some cases, one pair of terminal contacts 704 may be provided per wafer 102, or per-set of wafers 102. Accordingly, process steps typically associated with TSV formation may be omitted or abbreviated, where other TSV are not present. Conversely, in some embodiments, various TSV may be included for a data bus, memory, bus, clock, or other signal, and additional TSV may be provided for the terminal contacts 704 (e.g., in a front-to-back or back-to-back coupling).

A test structure 300 embedded in a substrate and laterally coextensive with scribe lines 702 may be present during the bonding process as may be coupled with a test device. Terminal contacts 704 can be disposed away from the scribe lines 702 to couple with at least a portion of contact pairs laterally coextensive with the scribe lines 702. That is, terminal contacts 704 can be placed away from scribe lines 702, even where the terminal contacts 704 are provided for a sacrificial test structure, to prevent burrs or delamination. In some cases, the test structure 300 is provided in or abutting an edge exclusion area, such that any area used for the test structure 300 does not reduce area available for other logic. In some cases, a test die is provided, which spans or abuts a scribe line 702 with a portion of contacts for contact pairs of the test structure 300 are located along or adjacent to the scribe line 702. For example, as depicted, the lower-right die 106 extends to a scribe line 702 such that any connections disposed below the other two depicted dies 106 are used as a portion of the test structure 300. At least a portion of the first or second contacts can be disposed within an active die area of this die 106, such as at to a lower portion of the die 106 extending beyond the other dies 106. Further, as is depicted, a (lower-left) die 106 is omitted to expose further connections, a portion of which may relate to test connections between the bonded pair.

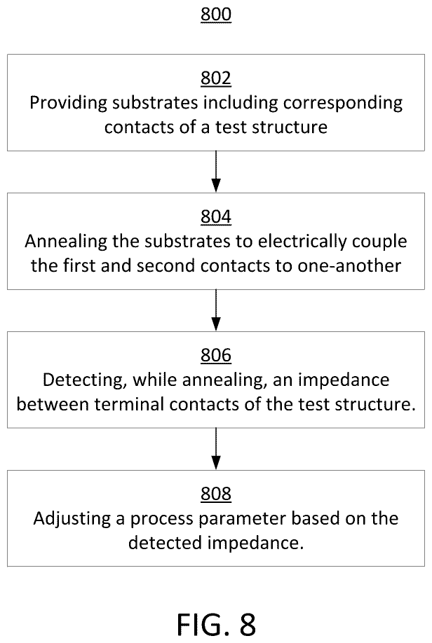

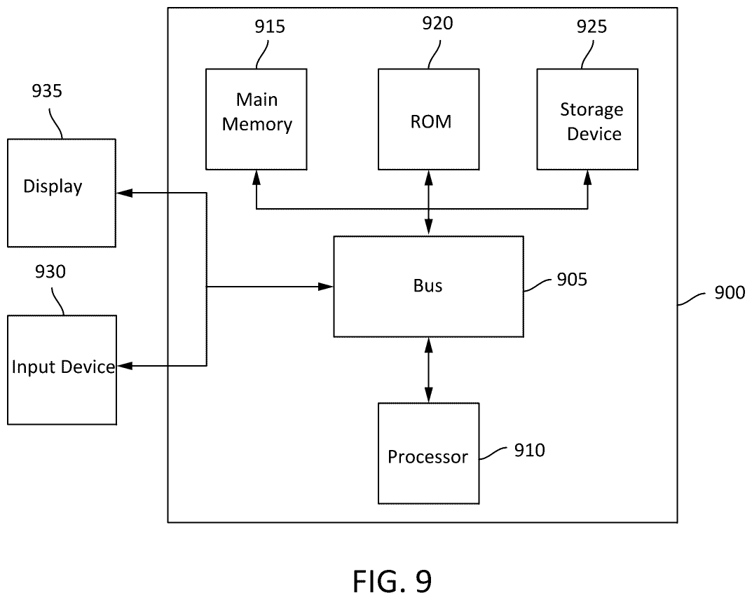

FIG. 8 is a flow chart of a method 800 for making a semiconductor device, in accordance with some embodiments. At least some operations of the method 800 may be performed according to instructions of a controller, such as a controller implementing a machine learning model of a data processing system. An example of such a controller is depicted henceforth, at FIG. 9. In brief overview, the method 800 starts with operation 802 of providing first and second substrates, each including corresponding contacts of a test structure 300. At operation 804, the method includes annealing the first and second substrates to electrically couple with first and second contacts with one-another. At operation 806, the method includes detecting, during the annealing of operation 804, an impedance between terminal contacts of the test structure 300. At operation 808, the method includes adjusting a process parameter based on the detected impedance.

Referring again to operation 802, the method 800 includes providing various first contacts 308 of a daisy chain structure on a first substrate and various second contacts 310 of the daisy chain structure on a second substrate. The first and second substrates can include any combinations of wafers and dies, (e.g., the first substrate can be a wafer 102 and the second substrate can be a die). The first contacts 308 and second contacts 310 can be configured to align with one-another to form contact pairs. The daisy chain structure can terminate at terminal contacts 704 on at least one of the first or second substrates. For example, the first substrate can include a first and second terminal contact 704 along a same surface coupled with the second substrate. Such terminal contacts 704 may be referred to as front-side terminal contacts. Backside terminal contacts 704 refer to a terminal contact 704 disposed away from an active surface of a substrate, as in the case of a terminal contact formed on a backside of a first substrate when the first and second substrate are coupled in a front-to-front configuration. Such a configuration may be used, for example, where a mating surface of the substrates is not available to couple to a probe of a test device.

A wafer 102 or other substrate can include various circuits, as may be bounded by scribe lines 702. Terminal contacts 704 may be provided for all, some, or no circuits of a particular wafer 102. That is, a terminal contact may be provided for one or more circuits of a wafer 102(e.g., only one), and omitted for other circuits. Such a configuration can reduce a number of connections with test probes of a test device. Moreover, in some embodiments, a subset of wafers can include the terminal contacts 704, and a status of further wafers can be determined based on any instrumented wafers. For example, one or more wafers 102 of a set of wafers 102 (medial, lower, or upper wafer 102 in a pod) can be instrumented and a condition of further wafers 102 can be predicted based on the instrumented wafers 102.

The daisy chain structure (sometimes referred to as a test structure 300) can include first contacts 308 or second contacts 310 disposed over a scribe line 702 of the first or second substrate. The daisy chain structure can include first contacts 308 and first lines 306 coupling the first contacts 308 to one-another (e.g., as depicted in FIG. 4). The daisy chain structure can include second contacts 310 and second lines 312 coupling the second contacts 310 to one-another. In some embodiments, the daisy chain structure, as coupled, consists of only, or essentially, the first contacts 308 and first lines 306, second contacts 310 and second lines 312, and any terminal contacts 704 coupled with the first and second contacts 310. The terminal contacts 704 can include, for example, a pad, TSV, and further routing lines, or a pad and lines according to various embodiments. The TSV can be exposed on a rear surface of the first substrate by removing a portion of the first substrate. This removal can refer to an etching, drilling, griding for wafer thinning, or other process. As indicated above, such as process can depart from other aspects of semiconductor manufacturing such as critical dimensions, in some embodiments. Where a daisy chained test structure 300 includes hundreds or thousands of contact pairs, a resistive contribution of the terminal contacts 704 can be substantially less than the contact pairs resistive contribution.

The resistive contribution may refer to an actual resistance or a variance in resistance (e.g., a test device can offset a measurement by a known amount to account for test probes or known portions of a circuit, such as the first lines 306 and second lines 312). Accordingly, variation in the TSV may be less critical than other applications, especially where all or a portion of a test structure 300 is disposed along a scribe line 702, edge exclusion area, dedicated test die or other sacrificial or other non-functional portion of a bonded pair of substrates. For example, a second substrate can laterally overlap with the scribe line 702 and include at least a portion of the plurality of the second contacts 310 within the boundaries of an active die area.

Referring again to operation 804, the method 800 includes annealing the first substrate and the second substrate to electrically couple the first contacts 308 with the second contacts 310. Annealing can refer to heating, as may be achieved using an annealing oven, a heated chuck, or other techniques. The annealing process can refer to an application of a temperature profile, as may include various annealing times (sometimes referred to as dwell times), annealing temperatures (sometimes referred to as dwell temperatures), and ramp rates between the temperatures. In some implementations, terminal contacts 704 for separate daisy chain structures can be provided for each of various circuits. For example, a heated chuck having various separately engageable heating zones can be configured to couple with separate daisy chain structures to detect a condition (e.g., continuity, impedance, etc.) of various of the test structures 300. Accordingly, operations 806 and 808 can be executed separately for each of various zones of the heated chuck. Moreover, further granularity can be achieved by interpolating a condition of circuits lacking a monitored test structure 300, or according to a predefined mapping according to a position (e.g., corresponding to a position-based relationship, such as a relationship between central and peripherally located circuits).

Referring again to operation 806, the method 800 includes detecting, while annealing the first substrate and the second substrate (e.g., simultaneous to operation 804), a measurement between a first terminal contact 704 of the daisy chain structure and a second terminal contact 704 of the daisy chain structure. The measurement can refer to an impedance (e.g., resistance) measurement, or other measurements as may be indicative of a coupling of corresponding paired contacts of the test structure 300. For example, the measurements can include a quantification of resistance, continuity, or so on. As indicated above, the measurement can be taken with respect to any number of instrumented test structures 300. For example, referring to the example of the heated chuck provided above, the measurement can be detected for each of the instrumented circuits.

Referring again to operation 808, the method 800 includes adjusting a process parameter (e.g., at least one of an annealing time or an annealing temperature) based on the measured property (e.g., resistance). The adjustment can be determined based on a mapping between an annealing temperature measurement (e.g., resistivity, continuity, impedance, or so forth). Accordingly, the method 800 can further include mapping an ambient resistance value to device yields. For example, yields may peak according to an ambient resistance of about 1 kΩ, as may correspond to halting annealing at a resistance of about 2 kΩ. That is, the annealing process may be halted at an annealing temperature resistance corresponding to an ambient resistance value correlating to a highest device yield. References to halting annealing should not be construed as limiting. For example, further process parameter variations can include initiating a ramp to an increased or decreased temperature, extending, or abbreviating a dwell time at a temperature, or so forth. As indicated above, in the case of the multi-zone chuck 700, the adjustment of operation 808 can include adjusting (or maintaining) a temperature of each of various separately (individually) engageable heating zones. The detection can further depend upon other dies 106, as may share a heating zone, or be based on adjoining heating zones (e.g., based on geometric interpolation). The separate zones can be engaged to converge the various measured values (e.g., resistances) towards a same value.

In some embodiments, various steps of the process may be based on (e.g., gated by) performance of additional checks. For example, a first example of a measurement includes a detection of continuity. Based on a detection of continuity, an annealing process can progress to another portion of a profile. For example, subsequent to the detection of continuity, a first process parameter can be adjusted. Subsequent to this adjustment a further measurement (e.g., an impedance) is detected and compared to a threshold (e.g., a binary threshold or a closest value in a mapping data structure) and used to adjust a second process parameter of the anneal process. The first and second process parameter can refer to adjustments to different times, temperatures, or phases of an anneal. In some embodiments, a phase terminates the anneal process, such as by entering a ramp to ambient temperatures. In some embodiments, measurements are taken regularly, (e.g., continuously or periodically, such as once per minute, once per second or so forth). The process can be iteratively adjusted based on the regularly taken measurements.

In some embodiments, methods of the present disclosure can include bonding (e.g., dielectric bonding) of a first substrate with a second substrate. The dielectric bond can mechanically couple the respective wafers, but need not electrically couple the substrates (e.g., a daisy chain or other electrically conductive test structure). The method can include monitoring a characteristic of the bonded first and second substrate. The characteristic can refer to a resistance or other impedance of a test structure (e.g., a daisy chain structure). For example, the characteristic can include a resistance of the method 800 of FIG. 8. Indeed, various aspects of method 800 of FIG. 8, or other aspects of the present disclosure can be incorporated into the present method, or the method 800 of FIG. 8 can be modified according to the present method (e.g., to include test structures other than daisy chain structures).

While monitoring the characteristic, the method can include annealing the first substrate and the second substrate under a set of conditions. For example, the set of conditions can include an annealing temperature, time, pressure, or other programmable aspect of an annealing chamber, heated chuck, or so forth. The method can include adjusting the set of conditions when the characteristic reaches a desired state. For example, the desired state can refer to a detected annealing temperature resistance as may correspond to an ambient temperate resistance (as described above with regard to the method 800 of FIG. 8). Such an ambient temperate resistance can correspond, in turn, to a device yield.

FIG. 9 depicts an example block diagram of an example computer system 900. The computer system or computing device 900 can include or be used to implement a data processing system or its components. The data processing system can instantiate, train store, and execute a machine learning model of the present disclosure. The computing system 900 includes at least one bus 905 or other communication component for communicating information and at least one processor 910 or processing circuit coupled to the bus 905 for processing information. The computing system 900 can also include one or more processors 910 or processing circuits coupled to the bus for processing information. The computing system 900 also includes at least one main memory 915, such as a random-access memory (RAM) or other dynamic storage device, coupled to the bus 905 for storing information, and instructions to be executed by the processor 710. The main memory 915 can be used for storing information during execution of instructions by the processor 910. The computing system 900 may further include at least one read only memory (ROM) 920 or other static storage device coupled to the bus 905 for storing static information and instructions for the processor 910. A storage device 925, such as a solid-state device, magnetic disk, or optical disk, can be coupled to the bus 905 to persistently store information and instructions.

The computing system 900 may be coupled via the bus 905 to a display 935, such as a liquid crystal display, or active-matrix display, for displaying information to a user such as a user disposed within a semiconductor fabrication facility or exterior thereto. An input device 930, such as a button or voice interface may be coupled to the bus 905 for communicating information and commands to the processor 910. The input device 930 can include a touch screen display 735. The input device 930 can also include a cursor control, such as a mouse, a trackball, or cursor direction keys, for communicating direction information and command selections to the processor 910 and for controlling cursor movement on the display 935.

The processes, systems and methods described herein can be implemented by the computing system 900 in response to the processor 910 executing an arrangement of instructions contained in main memory 915. Such instructions can be read into main memory 915 from another computer-readable medium, such as the storage device 925. Execution of the arrangement of instructions contained in main memory 915 causes the computing system 900 to perform the illustrative processes described herein. One or more processors in a multi-processing arrangement may also be employed to execute the instructions contained in main memory 915. Hard-wired circuitry can be used in place of or in combination with software instructions together with the systems and methods described herein. Systems and methods described herein are not limited to any specific combination of hardware circuitry and software.

Although an example computing system has been described in FIG. 9, the subject matter including the operations described in this specification can be implemented in other types of digital electronic circuitry, or in computer software, firmware, or hardware, including the structures disclosed in this specification and their structural equivalents, or in combinations of one or more of them.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments. “Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method comprising:
bonding a first substrate with a second substrate;
monitoring a characteristic of the bonded first and second substrate;
while monitoring, annealing the first substrate and the second substrate under a set of conditions; and
adjusting the set of conditions when the characteristic reaches a desired state.

2. The method of claim 1, wherein:
the first substrate is a wafer, and the second substrate is a die; and
the first substrate comprises, disposed along a same surface coupled with the die:
a first terminal contact for a plurality of first contacts of a daisy chain structure; and
a second terminal contact for a plurality of second contacts of the daisy chain structure.

3. The method of claim 2, wherein the first terminal contact comprises:
a through-substrate via structure, wherein the through-substrate via structure is exposed on a rear surface of the second substrate by removing a portion of the second substrate.

4. The method of claim 2, wherein:
the first substrate and the second substrate are coupled in a front-to-front configuration; and
the first terminal contact and the second terminal contact are disposed on a backside of the second substrate.

5. The method of claim 4, wherein the set of conditions comprises at least one of an annealing time or an annealing temperature and the desired state is determined using a resistance of an electrical connection between the first substrate and the second substrate.

6. The method of claim 1, further comprising:
mapping a plurality of annealing temperature resistance values of a daisy chain structure comprising a plurality of first contacts of the first substrate coupled with a plurality of second contacts of the second substrate to a corresponding plurality of ambient resistance values;
mapping the plurality of ambient resistance values to a plurality of device yields; and
halting the anneal responsive to detecting the resistance, wherein the desired state comprises a value of an annealing temperature resistance corresponding to an ambient resistance value correlating to a highest device yield.

7. The method of claim 6, wherein the first contacts and the second contacts are contacts of the daisy chain structure comprising contacts disposed over a scribe line of at least one of the first substrate or the second substrate.

8. The method of claim 6, wherein the daisy chain structure consists essentially of:
the first contacts and first lines coupling the first contacts to one-another;
the second contacts and second lines coupling the second contacts to one-another; and
first and second terminal contacts and any lines coupling the first and second terminal contacts with the first contacts.

9. The method of claim 5, wherein:
the second substrate laterally overlaps with a scribe line and comprises at least a portion of the plurality of second contacts within an active die area.

10. The method of claim 1, further comprising:
annealing the first substrate with the second substrate using a heated chuck having a plurality of separately engageable heating zones, wherein further terminal contacts are coupled with further daisy chain structures;
adjusting the set of conditions comprises adjusting a first temperature of a first of the plurality of separately engageable heating zones based on a detected resistance; and
adjusting the set of conditions comprises adjusting a second temperature of a second of the plurality of separately engageable heating zones based on a second detected resistance, the second detected resistance detected via one of the further terminal contacts.

11. The method of claim 10, further comprising:
separately engaging the separately engageable heating zones to individually control bonding of the first substrate with the second substrate and a plurality of further substrates, based on:
a plurality of other detected resistances corresponding to annealing with each of the further substrates, wherein:
the first substrate is a wafer; and
the second substrate and the further substrates are cut dies.

12. A method comprising:
bonding a first substrate comprising a plurality of first contacts to a second substrate comprising a plurality of second contacts;
heating the first and second substrates to a first temperature configured to electrically couple the plurality of first contacts with corresponding ones of the plurality of second contacts;
detecting, at the first temperature, continuity between a first terminal contact and a second terminal contact coupled with the plurality of first and second contacts;
adjusting, based on the detection of continuity, a first process parameter of an anneal process to couple the first substrate with the second substrate;
detecting, subsequent to adjusting the first process parameter, an impedance between the first terminal contact and the second terminal contact; and
adjusting, based on the detection of continuity, a second process parameter of the anneal process based on a comparison of the impedance to an impedance threshold.

13. The method of claim 12, wherein the adjustment to the second process parameter comprises a termination of the anneal process.

14. The method of claim 12, wherein the impedance is a resistance.

15. The method of claim 12, wherein the adjustment to the first process parameter comprises:
an adjustment to an annealing time; or
an adjustment to an annealing temperature.

16. The method of claim 15, wherein the method further comprises:
comparing the impedance to a mapping between the first temperature and another impedance at a second temperature; and
terminating the annealing process based on the mapping.

17. The method of claim 15, further comprising:
regularly detecting the impedance; and
iteratively adjusting the second process parameter.

18. A system comprising:
a heated chuck comprising:
a plurality of separately engageable heating zones; and
a plurality of terminal pairs configured to couple with corresponding terminals of a semiconductor device comprising a first substrate and at least one second substrate; and
a controller configured to:
receive, from the plurality of terminal pairs, a corresponding plurality of measurements at the plurality of terminal pairs; and
adjust, based on the plurality of measurements, a temperature of the separately engageable heating zones.

19. The system of claim 18, wherein:
the plurality of measurements comprise a plurality of resistance measurements; and
the controller is further configured to:
compare the plurality of resistance measurements to a threshold resistance value; and
adjust the temperature of the separately engageable heating zones to converge the plurality of resistance measurements to a same value.

20. The system of claim 19, wherein the same value is an ambient temperature resistance value.
